(19) United States
(12) Patent Application Publication
(10) Pub. No.: US 2021/0063823 A1
(43) Pub. Date: Mar. 4, 2021

(54) DISPLAY PANEL, DISPLAY PANEL MANUFACTURING METHOD, AND DISPLAY DEVICE

(71) Applicant: TCL CHINA STAR OPTOELECTRONICS TECHNOLOGY CO., LTD., Shenzhen, Guangdong (CN)

(72) Inventor: Yu ZHANG, Shenzhen, Guangdong (CN)

(21) Appl. No.: 16/619,086

(22) PCT Filed: Nov. 13, 2019
(86) PCT No.: PCT/CN2019/117862

§ 371 Date: Dec. 4, 2019

(30) Foreign Application Priority Data
Sep. 3, 2019 (CN) 201910837671.6

(51) Int. Cl. G02F 1/1337; G02F 1/1335

(52) U.S. Cl. CPC G02F 1/133703; G02F 1/133514; G02F 2001/133726; G02F 1/133711; G02F 1/133528

(57) ABSTRACT

The present invention provides a display panel, a manufacturing method, and display device thereof. By disposing a mesoporous guide film on a surface of an alignment layer and using evenly distributed mesopores in the mesoporous guide film with a same tilt angle, the liquid crystal molecules are tilted along the mesopores under applied voltage and stand in pore channels of the mesopores to mitigate the issue of poor reliability when the display device implements stable alignment, lower manufacturing cost, improve yield rate of products, and shorten time of processes.

### FIELD OF INVENTION

The present invention relates to a field of display technologies, especially to a display panel, a display panel manufacturing method, and a display device including the display panel.

### BACKGROUND OF INVENTION

Advances in technology have led to the continuous development of display technology. Liquid crystal displays as the most widely used display technology, also begins to develop in new directions. How to reduce the manufacturing cost of display panel and display device while improving display performance on the original basis, and how to realize the intelligent alignment of liquid crystal molecules and develop intelligent liquid crystal display panels gradually become an important developing direction of the liquid crystal displaying technologies.

Because a liquid crystal display device employs a working principle of passive light emission, variation of an angle of view has great influence to perception of images. A response speed of a display device to signals has great influence to smooth display. Therefore, contrast and a response time are two important indexes for evaluating performance of a display device. In the conventional technologies, to improve contrast and shorten a response time, generally in a vertical alignment type liquid crystal display device, an alignment method with stable polymer is usually used, i.e., a polymer stabilized vertical alignment (PSVA) method. Monomers of polymer are added into a liquid crystal molecule layer, and then adequate voltage and light radiation are exerted thereon such that monomers of the polymer are polymerized to form a polymeric layer with a pre-tilt angle that can rivet liquid crystal molecules.

Although employing the polymer stabilized vertical alignment (PSVA) method can extremely increase contrast of the display device and shorten the response time, shortages thereof can not be ignored. Because adding monomers of polymer into a liquid crystal molecule layer is necessary, manufacturing cost of the display panel is increased. Furthermore, in different composition structures of liquid crystal, there is an existing risk of excessively high amounts of residue of ingredients of the monomers of polymer, which easily incurs an issue of reliability and affects the quality of the display panel.

### SUMMARY OF INVENTION

### Technical Issue

The present invention provides a display panel and a manufacturing method, display device o solve the technical issue that a conventional display device achieves stable alignment by using polymer to increase contrast and a response time and results in an increased cost of products and poor reliability.

[symbol]

### Technical Solution

To solve the above issue, the present invention provides technical solutions as follows.

The present invention provides a display panel, comprising an array substrate, a color filter substrate disposed opposite to the array substrate, and a mesoporous guide film and liquid crystal molecules located between the array substrate and the color filter substrate;

wherein the mesoporous guide film comprises mesopores, the mesopores have a same tilt angle, and distributed evenly, and the liquid crystal molecules stand in pore channels of the mesopores when an external voltage is exerted thereon such that liquid crystal alignment is accomplished.

According to a preferred embodiment of the present invention, the mesoporous guide film is formed on a surface of an alignment layer on the array substrate or the color filter substrate near the liquid crystal molecules. Because the mesopores comprises pore channels connectivity characteristic, a physical force is still between a branched chain of the alignment layer and the liquid crystal molecules.

When no voltage is exerted thereon, the liquid crystal molecules are in an upright status, and are arranged vertically to the array substrate and the color filter substrate. Because an upper polarizer and a lower polarizer on the display panel are orthogonal to each other, linearly polarized light are blocked entirely, and at the same time the display panel is complete dark. After voltage is exerted thereon, the liquid crystal molecules rotate to stand in the pore channels of the mesopores. Because the mesopores are at an tilt angle, the liquid crystal molecules standing in the pore channels are spatially limited by the mesopores in a certain degree, so the liquid crystal molecules are arranged at the tilt angle. At the meantime a part of light is emitted out from the polarizer, and the display panel is bright to display.

According to a preferred embodiment of the present invention, the mesoporous guide film comprises: a first mesoporous guide film formed on a surface of an alignment layer of the array substrate near the liquid crystal molecules; and a second mesoporous guide film formed on a surface of an alignment layer of the color filter substrate near the liquid crystal molecules.

First mesopores are defined in the first mesoporous guide film, and the first mesopores include a same tilt angle, and are distributed evenly; second mesopores are defined in the second mesoporous guide film, and the second mesopores include a same tilt angle, and are distributed evenly; and the tilt angle of the first mesopores is the same as the tilt angle of the second mesopores, and the second mesopores are arranged on an extension line of the first mesopores extending along the tilt angle.

According to a preferred embodiment of the present invention, a pore wall of each of the mesopores of the mesoporous guide film is decorated with functional molecules, the functional molecules are different according to different functions to be achieved. The functional molecules can comprise but are not limited to the following: Azobenzene molecules with a photoresponse characteristic are disposed on the pore wall to assist the liquid crystal molecules to accomplish light alignment; thermosensitive polymer is disposed on the pore wall to fasten the liquid crystal molecules under a heating condition; pH sensitive molecules are disposed on the pore wall to fasten the liquid crystal molecules under a specific pH value; hydrophilic molecules or hydrophobic molecules are disposed on the pore wall. The functional molecules are adjusted according to different compositions of liquid crystal.

A method for manufacturing the functional molecules can employ a coating process to distribute molecules in a specific solution to form a reaction solution, and then coat the reaction solution on a surface of a film layer of the mesopores. Depending on different characteristics of different reaction solution, different reaction conditions are set, for example, modification and graft under silane coupling reaction with an anhydrous condition are successful. Then redundant reaction solution is removed.

The present invention discloses a display panel manufacturing method, comprising:

step S1 providing an array substrate and a color filter substrate, wherein an alignment layer is formed on the array substrate and the color filter substrate, and a mesoporous guide film is formed on at least one surface of the alignment layer;

step S2 bonding the array substrate and the color filter substrate, and filling liquid crystal molecules between the array substrate and the color filter substrate;

step S3 attaching an upper polarizer and a lower polarizer and assembling a module.

The step S1 further comprises:

step S11 co-assembling a mold release agent and a precursor to form a composite structure; and

step S12 removing the mold release agent to form a mesoporous guide film.

The surface of the alignment layer is a side thereof near the liquid crystal molecules.

In a common vertical alignment type liquid crystal display mode, a way of disposing a first mesoporous guide film and a second mesoporous guide film can be employed, in other words, a second mesoporous guide film is disposed on a surface of an alignment layer of the color filter substrate near the liquid crystal molecules. The mesoporous guide film on the array substrate is the first mesoporous guide film.

In a self-assembling liquid crystal display mode, a structure of disposing the mesoporous guide film on a single side can be employed, in other words, a mesoporous guide film is disposed on a surface of the alignment layer on the array substrate near the liquid crystal molecules; or a mesoporous guide film is disposed on a surface of the alignment layer on the color filter substrate near the liquid crystal molecules.

The mold release agent is a surfactant, the surfactant is a block copolymer containing polyoxyethylene or polyoxypropylene and comprises but not is not limited to polystyrene-block-poly(ethylene oxide) (PS-b-PEO), Poly(ethylene oxide)-block-poly(methyl methacrylate) (PEO-b-PMMA), Poly(ethylene oxide)-block-poly(4-vinylpyridine) (PEO-b-P4VP). The precursor comprises carbon base, carbon base, metal, and metal oxide.

Because interaction between the surfactant and the precursor in compositing of ordered mesoporous material play critical roles, and determine formation of the structure of the mesoporous, a proportion of the surfactant to the precursor is 1:3-1:17. Structures of the pore channels of the mesopores can be adjusted by adjusting different mold release agents. The structure of the pore channels comprises but is not limited to a two-dimensional regular hexagonal structure, and a laminated structure.

The present invention further provides a display device comprising the above display panel.

### Advantages

Compared to a conventional display panel, a conventional manufacturing method, and a conventional display device thereof employing polymer to achieve stable alignment, the display panel, the manufacturing method, and the display device thereof of the present invention. By disposing the mesoporous guide film including the evenly distributed mesopores with the same tilt angle on the surface of the alignment layer such that the liquid crystal molecules under a applied voltage condition can be tilted along the tilt angle of the mesopores, which achieves stable alignment, extremely lowers manufacturing cost, improves a yield rate of products, reduces processing time, and avoids the issue of poor reliability due to residue of polymer monomers.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may acquire other figures according to the appended figures without any creative effort.

FIGS. 1A and 1B are schematic structural views of a display panel of the present invention;

FIG. 2 is a schematic structural view of another display panel of the present invention.

FIG. 3 is a schematic view of a display panel manufacturing method of the present invention.

FIG. 4 is a schematic structural view of mesopores of the display panel of the present invention;

FIG. 5 is a schematic structural view of mesopores of the display panel of the present invention decorated with functional molecules for completing various alignments of the liquid crystal molecules.

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention. In the figures, units with similar structures are marked with the same reference characters.

The present invention aims at the issue that a conventional display device achieves stable alignment by using polymer to increase contrast and a response time and results in an increased cost of products and poor reliability. The present embodiment can solve the defects.

### First Embodiment

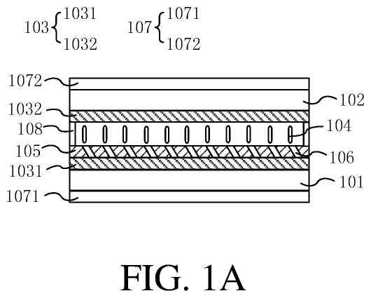

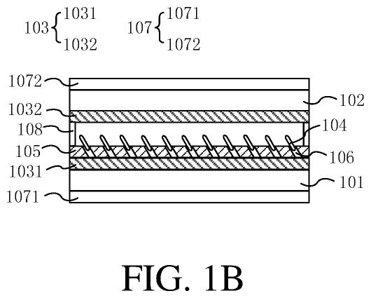

FIGS. 1A and 1B are schematic structural views of a display panel of the present invention. The display panel comprises an array substrate 101, a color filter substrate 102 disposed opposite to the array substrate 101, a frame sealant 108, and liquid crystal molecules 104 and a mesoporous guide film 105 disposed between the array substrate 101 and the color filter substrate 102.

An alignment layer 103 is disposed on a surface of a side of each of the array substrate 101 and the color filter substrate 102 near the liquid crystal molecules 104. The alignment layer 103 comprises: a first alignment layer 1031 disposed a side of the array substrate 101 near the liquid crystal molecules 104; and a second alignment layer 1032 disposed on a side of the color filter substrate 102 near the liquid crystal molecules. The mesoporous guide film 105 is disposed on a surface of a side of the first alignment layer 1031 away from the array substrate 101. Mesopores 106 are defined in the mesoporous guide film 105, are distributed evenly, and include a same tilt angle.

Because the mesopores 106 have a pore channel connectivity characteristic, a physical force is still between the first alignment layer 1031 and the liquid crystal molecules 104. The first alignment layer 1031 and the second alignment layer 1032 are made of stock solution containing small molecule compounds, and are polymerized under a high temperature. A force between branched chain groups of these polymer and the liquid crystal molecules 104 are stronger, and can anchor the liquid crystal molecules 104 such that the liquid crystal molecules 104 are arranged according to a pre-tilt angle of the mesopores 106. In the present embodiment, the alignment layer 103 is a polyimide alignment layer, and a person having ordinary skill in the art can choose alignment layer of other material as needed.

With reference to FIG. 1A, FIG. 1A is a schematic view of a distribution status of liquid crystal molecules of the display panel without voltage applied thereto. When no voltage is applied, the liquid crystal molecules 104 are vertical to surfaces of the array substrate 101 and the color filter substrate 102, and are in an upright status. At the meantime, because upper and lower surfaces of the display panel are disposed with a polarizer 107, and an upper polarizer 1072 and a lower polarizer 1071 are orthogonal to each other, linearly polarized light will be entirely blocked such that the display panel is in an entire dark status.

With reference to FIG. 1B, FIG. 1B is a schematic view of a distribution status of liquid crystal molecules of the display panel applied with voltage. After voltage is applied, the liquid crystal molecules 104 rotate and stand in the pore channels of the mesopores 106. Because the mesopores 106 are at the tilt angle, the liquid crystal molecules 104 standing in the pore channels are spatially limited by the mesopores in a certain degree, so the liquid crystal molecules 104 are also arranged at the tilt angle. At the meantime a part of light is emitted out from the polarizer, and the display panel is bright to display.

Besides the structures of the display panel in FIGS. 1A to 1B, the mesoporous guide film 105 can only be disposed on a surface of a side of the second alignment layer 1032 near the liquid crystal molecules 104. Similarly, mesopores 106 are defined in the mesoporous guide film 105, are distributed evenly and have a same tilt angle. Under an applied voltage, the liquid crystal molecules 104 are tilted at the pre-tilt angle of the mesopores 106 such that display panel becomes bright to display.

In a self-assembling liquid crystal display mode, a structure of disposing the mesoporous guide film 105 on a single side can be employed, in other words, the mesoporous guide film 105 is disposed on a surface of the first alignment layer 1031 of the array substrate 101 near the liquid crystal molecules 104; or the mesoporous guide film 105 is disposed on a surface of the second alignment layer 1032 of the color filter substrate 102 near the liquid crystal molecules 104.

In the self-assembling liquid crystal display mode provided by the present embodiment, the structural formation of the mesoporous guide film 105 on the single side can be used for explanation, it is auxiliary for understanding the present invention, but is not configured to limit an application extent of the present invention. A person having ordinary skill in the art can apply it in other display panels according to actual need.

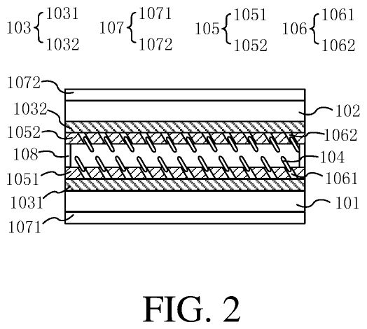

FIG. 2 is a schematic structural view of another display panel of the present invention employing reference numerals the same as those in FIGS. 1A and 1B. The mesoporous guide film 105 comprises: a first mesoporous guide film 1051 formed on a surface of a side of the first alignment layer 1031 near the liquid crystal molecules 104; and a second mesoporous guide film 1052 formed on a surface of a side of the second alignment layer 1032 near the liquid crystal molecules.

First mesopores 1061 are defined in the first mesoporous guide film 1051 include a same tilt angle, and are distributed evenly; second mesopores 1062 are defined in the second mesoporous guide film 1052 include a same tilt angle, and are distributed evenly; the tilt angle of the first mesopores 1061 is the same as the tilt angle of the second mesopores 1062, the second mesopores 1062 are arranged on an extension line of the first mesopores 1061 extending along the tilt angle such that the tilt angles are consistent when the liquid crystal molecules 104 achieves stable alignment.

When no voltage is applied, the liquid crystal molecules 104 are in an upright status, and the display panel is in an entire dark status; when voltage is applied, the liquid crystal molecules 104 stand in pore channels of the first mesopores 1061 and the second mesopores 1062, and the display panel becomes bright to display.

With reference to FIG. 2, the structure formation with mesoporous guide films on two sides can be applied to a common vertical alignment type liquid crystal display mode, and can also applied to other display modes. The structure formation with mesoporous guide films on two sides applied in the vertical alignment type liquid crystal display mode of the present invention is merely for facilitating understanding the present invention, but is not configured to limit an application extent of the present invention. A person having ordinary skill in the art can apply it in other display panels according to actual need.

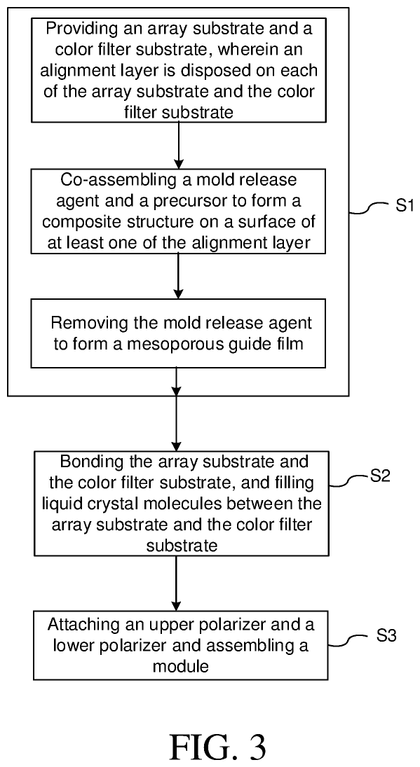

With reference to FIG. 3, a display panel manufacturing method, comprises: step S1, step S2, and step S3.

The step S1 is providing an array substrate and a color filter substrate, wherein an alignment layer is formed on the array substrate and the color filter substrate, and a mesoporous guide film is formed on at least one surface of the alignment layer.

The step S2 is bonding the array substrate and the color filter substrate, and filling liquid crystal molecules between the array substrate and the color filter substrate.

The step S3 is attaching an upper polarizer and a lower polarizer and assembling a module.

The step S1 further comprises: step S11 and step S12.

The step S11 is co-assembling a mold release agent and a precursor to form a composite structure

The step S12 is removing the mold release agent to form a mesoporous guide film.

The surface of the alignment layer is a side thereof near the liquid crystal molecules.

### Second Embodiment

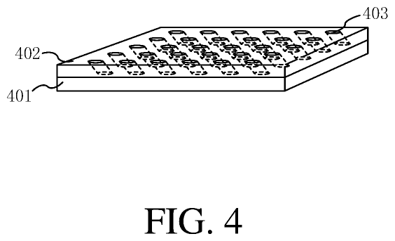

FIG. 4 is a schematic structural view of mesopores of the display panel. The mesopores 403 are distributed evenly on mesoporous guide film 402, and the mesopores 403 are tilted by a predetermined tilt angle. A diameter of the mesopores 403 is adjusted according to a dimension of liquid crystal molecules, and an adjustable range is 2 nm-50 nm.

The mesoporous guide film 402 is disposed on a surface of the alignment layer 401, a method for manufacturing the mesoporous guide film 402 can be a soft templating method or a hard templating method. When a soft templating method is employed, a mold release agent and a precursor are co-assembled to form a composite structure, and then the mold release agent is removed to manufacture the mesoporous guide film 402 on a surface of the alignment layer 401. A process of removing the mold release agent comprises but is not limited to high temperature baking, ultraviolet light irradiation, and solvent washing.

The mold release agent is a surfactant, the surfactant is a block copolymer containing polyoxyethylene or polyoxypropylene and comprises but not is not limited to polystyrene-block-poly(ethylene oxide) (PS-b-PEO), Poly(ethylene oxide)-block-poly(methyl methacrylate) (PEO-b-PMMA), Poly(ethylene oxide)-block-poly(4-vinylpyridine) (PEO-b-P4VP). The precursor comprises carbon base, carbon base, metal, and metal oxide.

Because interaction between the surfactant and the precursor in compositing of ordered mesoporous material play critical roles, and determine formation of the structure of the mesopores 403, a proportion of the surfactant to the precursor can be set as 1:3-1:17. Structures of the pore channels of the mesopores 403 can be adjusted by adjusting different mold release agents. The structure of the pore channels comprises but is not limited to a two-dimensional regular hexagonal structure, and a laminated structure.

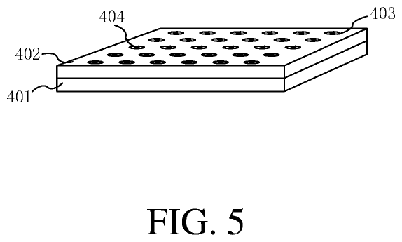

FIG. 5 is a schematic structural view of mesopores of the display panel of the present invention decorated with functional molecules for completing various alignments of the liquid crystal molecules with reference numerals the same as those in FIG. 4. A pore wall of each of the mesopores 403 on the mesoporous guide film 402 is decorated with functional molecules 404, and the functional molecules 404 are different according different functions to be achieved. The functional molecules 404 and comprise but is not limited to functional molecules as follows: azobenzene molecules, thermosensitive polymer, pH sensitive molecules.

Azobenzene molecules with a photoresponse characteristic is disposed on the pore walls of the mesopores 403, to assist the liquid crystal molecules to accomplish light alignment. Thermosensitive polymer is disposed on the pore walls of the mesopores 403 and can fasten the liquid crystal molecules under a heating condition. PH sensitive molecules are disposed on the pore wall of the mesopores 403 and can fasten the liquid crystal molecules under a specific pH value. Furthermore, the functional molecules 404 can also be adjusted according to different compositions of liquid crystal, for example, hydrophilic molecules or hydrophobic molecules are disposed on the pore walls of the mesopores 403 to achieve fastening different liquid crystal molecules.

A method for manufacturing the functional molecules 404 can employ a coating process to distribute the functional molecules 404 in a specific solution to form a reaction solution, and then coat the reaction solution on a surface of a film layer of the mesopores 403. Depending on different characteristics of different reaction solution, different reaction conditions are set, for example, modification and graft under silane coupling reaction with an anhydrous condition are successful. Then redundant reaction solution is removed to manufacture the mesoporous guide film 402 with the pore wall of the mesopores 403 decorated with functional molecules.

Although the preferred embodiments of the present invention have been disclosed as above, the aforementioned preferred embodiments are not used to limit the present invention. The person of ordinary skill in the art may make various changes and modifications without departing from the spirit and scope of the present invention. Therefore, the scope of protection of the present invention is defined by the scope of the claims.

What is claimed is:

1. A display panel, comprising an array substrate, a color filter substrate disposed opposite to the array substrate, and a mesoporous guide film and liquid crystal molecules located between the array substrate and the color filter substrate;
wherein the mesoporous guide film comprises mesopores, the mesopores have a same tilt angle, and distributed evenly, and the liquid crystal molecules stand in pore channels of the mesopores when an external voltage is exerted thereon such that liquid crystal alignment is accomplished.

2. The display panel as claimed in claim 1, wherein the mesoporous guide film is formed on a surface of an alignment layer on the array substrate or the color filter substrate near the liquid crystal molecules.

3. The display panel as claimed in claim 2, wherein a branched chain of the alignment layer anchors the liquid crystal molecules through a connectivity characteristic of pore channels of the mesopores.

4. The display panel as claimed in claim 1, wherein a diameter of each of the mesopores is adjustable according to variation of a size of each of the liquid crystal molecules, and an adjustable range of the diameter is 2 nm-50 nm.

5. The display panel as claimed in claim 1, wherein the mesoporous guide film comprises: a first mesoporous guide film formed on a surface of an alignment layer of the array substrate near the liquid crystal molecules; and a second mesoporous guide film formed on a surface of an alignment layer of the color filter substrate near the liquid crystal molecules.

6. The display panel as claimed in claim 5, wherein first mesopores are defined in the first mesoporous guide film, and the first mesopores include a same tilt angle, and are distributed evenly; second mesopores are defined in the second mesoporous guide film, and the second mesopores include a same tilt angle, and are distributed evenly; and the tilt angle of the first mesopores is the same as the tilt angle of the second mesopores, and the second mesopores are arranged on an extension line of the first mesopores extending along the tilt angle.

7. The display panel as claimed in claim 1, wherein a pore wall of each of the mesopores of the mesoporous guide film is decorated with functional molecules, the functional molecules comprise azobenzene molecules, thermosensitive polymer, pH sensitive molecules, hydrophilic molecules or hydrophobic molecules.

8. A display panel manufacturing method, comprising:
step S1 providing an array substrate and a color filter substrate, wherein an alignment layer is formed on the array substrate and the color filter substrate, and a mesoporous guide film is formed on at least one surface of the alignment layer;
step S2 bonding the array substrate and the color filter substrate, and filling liquid crystal molecules between the array substrate and the color filter substrate;
step S3 attaching an upper polarizer and a lower polarizer and assembling a module.

9. The manufacturing method as claimed in claim 8, wherein the step S1 further comprises:
step S11 co-assembling a mold release agent and a precursor to form a composite structure; and
step S12 removing the mold release agent to form a mesoporous guide film.

10. The manufacturing method as claimed in claim 8, wherein the surface of the alignment layer is a side thereof near the liquid crystal molecules.

11. The manufacturing method as claimed in claim 9, wherein the mold release agent is a surfactant, the surfactant is a block copolymer containing polyoxyethylene or polyoxypropylene and comprises one of Polystyrene-block-poly(ethylene oxide) (PS-b-PEO), poly(ethylene oxide)-block-poly(methyl methacrylate) (PEO-b-PMMA), and Poly(ethylene oxide)-block-poly(4-vinylpyridine) (PEO-b-P4VP).

12. The manufacturing method as claimed in claim 9, wherein the precursor comprises one of carbon base, carbon base, metal, and metal oxide.

13. The manufacturing method as claimed in claim 9, wherein formation of mesopores of the mesoporous guide film is influenced by a surfactant of the mold release agent and the precursor, a proportion of the surfactant to the precursor is 1:3-1:17.

14. The manufacturing method as claimed in claim 9, wherein pore channels of mesopores of the mesoporous guide film is acquired by adjusting various structures of the mold release agent, and a structure of each of the pore channels of the mesopores comprises a two-dimensional regular hexagonal structure, and a laminated structure.

15. A display device, comprising the display panel as claimed in claim 1.
